(19) United States
(12) Patent Application Publication
(10) Pub. No.: US 2026/0128074 A1
(43) Pub. Date: May 7, 2026

(54) CAPACITORLESS MEMORY CELL AND MEMORY DEVICE COMPRISING THE SAME

(71) Applicant: Seoul National University R&DB foundation, Seoul (KR)

(72) Inventor: Cheol Seong Hwang, Seoul (KR)

(21) Appl. No.: 19/377,857

(22) Filed: Nov. 3, 2025

(30) Foreign Application Priority Data
Oct. 23, 2025 (KR) 10-2025-0154425
Nov. 5, 2024 (KR) 10-2024-0155482

(51) Int. Cl. G11C 11/405; G11C 11/4091

(52) U.S. Cl. CPC G11C 11/405; G11C 11/4091

(57) ABSTRACT

The present disclosure provides a capacitorless semiconductor memory device including a plurality of a semiconductor memory cell arrays comprising a plurality of semiconductor memory cells including a write transistor and a read transistor, the read transistor including a drain region, a control electrode, and a source region; a diode connected to the source region of the read transistor; and a sensing amplifier in connection with a read bit line, wherein the semiconductor memory device has a capacitorless structure that does not include a storage capacitor.

### CROSS-REFERENCE TO RELATED APPLICATION

This application claims priority of Korean Patent Application No. 10-2024-0155482, filed on November 5, 2024, and priority of Korean Patent Application No. 10-2025-0154425, filed on October 23, 2025, in the KIPO (Korean Intellectual Property Office), the disclosure of which is incorporated herein entirely by reference.

### BACKGROUND OF THE INVENTION

### Field of the Invention

The present invention relates to semiconductor memory device technology, and more particularly to a capacitorless memory cell and a memory device comprising the same.

### Description of the Related Art

Today, dynamic random access memory (DRAM), a semiconductor memory that randomly writes and reads data at high speed, is widely used in data storage devices or devices. DRAM includes a plurality of repeated memory cells, each of which typically includes a capacitor configured to store data information and a transistor configured to control the reading of data information from the capacitor structure.

To facilitate the integrated development of such memory cells, a related art has developed techniques for using memory cells in a 2T0C structure. The 2T0C structure uses two transistors as memory elements and does not include a capacitor, which reduces the volume occupied by the memory cell. In addition, neighboring memory cells may be organized by sharing word lines and bit lines.

However, these 2T0C DRAMs may suffer from interference when reading a selected cell depending on the state of neighboring cells that share word lines and bit lines. For example, if the selected cell is off (data 0) and the three neighboring cells are all on (data 1), the selected cell has a higher probability of being interfered with by the three neighboring cells.

Therefore, there is a great need to develop a 2TOC circuit that may solve the problem of interference between neighboring memory cells. In particular, since DRAM may be used not only as a memory but also as a neuromorphic device for artificial intelligence, according to today's technology trends, it is necessary to develop a 2T0C circuit that may be used without interference from neighboring cells and without data reading errors.

### SUMMARY OF THE INVENTION

The technical challenge of the present invention is to provide an asymmetric electrode structure and memory cells that may be used in memory requiring error-free and accurate operation as well as neuromorphic devices for artificial intelligence by preventing leakage currents between neighboring cells to read selected cells without interference from neighboring cells.

Furthermore, by implementing a capacitorless structure that does not include a capacitor, it is possible to provide a capacitorless memory device that is advantageous for high integration and improves the reading margin by reducing inter-cell interference.

A capacitorless semiconductor memory device according to one embodiment of the present invention includes a plurality of memory cells comprising write transistors and read transistors, the read transistors comprising a memory cell array including a drain region, a control electrode, and a source region; a diode connected to the source region of the read transistors; and a sensing amplifier connected to the read bit line.

Leakage current from the read word line to the read bit line is blocked by the diode when an operating voltage value (V_{dd})is applied to a non-selective memory cell among the memory cells included in the memory cell array.

Further, the capacitorless semiconductor memory device further comprises a clamping circuit connected in parallel with the sensing amplifier, the clamping circuit causing a minimum value of the voltage on the read bit line to be a clamping voltage value.

Further, when the read bit line voltage of a non-selected memory cell of the memory cell is set to 0V and the read word line voltage is set to an operating voltage value (V_{dd}), a voltage value between a drain region and a source region of the non-selected memory cell may be a value of the operating voltage value (V_{dd})minus a diode voltage value (V_{diode}).

Further, a capacitorless semiconductor memory device according to another embodiment of the present invention includes a memory cell array comprising a plurality of memory cells including a write transistor and a read transistor; a bit line connected with a source region of the read transistor; and a sensing amplifier connected with the bit line, wherein the contact material of the source region of the read transistor comprises a Schottky contact material.

The read transistor includes an IGZO channel comprising at least one of indium, gallium, zinc, and oxygen.

Further, the source contact of the read transistor may include a material having a work function of at least 4.7 eV.

Further, the source contact of the read transistor may include Ru, Au, Pd, Ni, Pt, or an alloy thereof.

Further, the drain contact of the read transistor may be a material constituting an ohmic contact.

Further, the drain contact of the read transistor comprises at least one of Ti, TiN, Al, and alloys thereof.

Further, the read transistor may comprise an IGZO channel comprising at least one of indium, gallium, zinc, and oxygen, wherein the contact material of the source region is Pt or a Pt alloy material, and the drain region may be Ti or a Ti alloy material.

Further, the capacitorless semiconductor memory device further comprises a clamping circuit in parallel connection with the sensing amplifier, the clamping circuit causing a minimum value of a voltage on the read bit line to be a clamping voltage value.

A semiconductor memory cell according to one embodiment of the present invention, comprising: a first transistor comprising a p-type semiconductor channel layer; a second transistor connected in series to the first transistor; a memory element connected to a path in which the first transistor and the second transistor are connected in series; and a memory cell comprising a source contact contacting a source region and a drain contact contacting a drain region of the first transistor, wherein the source contact is formed of a low work function metal to inhibit current flow in the drain-source direction by increasing a hole injection barrier at the interface with the p-type semiconductor channel layer, and wherein the drain contact is formed of a high work function metal to facilitate hole injection, and wherein the memory cell may be implemented as a capacitorless structure that does not include a separate storage capacitor.

In one embodiment, the low work function metal may comprise aluminum, titanium, silver, or combinations thereof, and the high work function metal may comprise platinum, ruthenium, palladium, or combinations thereof.

The first transistor may comprise a p-type oxide semiconductor channel layer.

In one embodiment, the memory device may store a charge in a storage node of a path in which the first transistor and the second transistor are connected in series.

The first transistor may be a read transistor, and the second transistor may be a select transistor.

A semiconductor memory device according to another embodiment of the present invention, comprising: a plurality of memory cell arrays disposed in a cross-array structure on a substrate; a plurality of read bit line (RBL) and write bit line (WBL) pairs and a plurality of read word line (RWL) and write word line (WWL) pairs associated with the memory cell arrays; a first transistor, a second transistor, and a memory element connected in series to the first and second transistors having a p-type semiconductor channel layer included in each of the memory cells; a source contact in contact with a source region of the first transistor and a drain contact in contact with a drain region of the second transistor; and a read circuit connected to the read bit line and write bit line pair to perform a read operation, wherein the source contact is formed of a low work function metal to increase a hole injection barrier at the interface with the p-type semiconductor channel layer to block leakage current from the read word line to the read bit line in unselected memory cells, wherein the drain contacts are formed of a high work function metal to facilitate hole injection, and wherein the memory device may be implemented as a capacitorless structure that does not include a separate storage capacitor.

In one embodiment, the low work function metal may comprise aluminum, titanium, silver, or combinations thereof, the high work function metal may comprise platinum, ruthenium, palladium, or combinations thereof, and the first transistor may comprise a p-type oxide semiconductor channel layer.

In one embodiment, the semiconductor memory device may store a charge in a storage node of a path in which the first transistor and the second transistor are connected in series.

The first transistor may be a read transistor, and the second transistor may be a select transistor.

A read margin of the entire memory array may be formed by suppression of the leakage current, and the read circuitry may include a sense amp.

According to embodiments of the present invention, a semiconductor memory device that is effective in reading only data from selected memory cells and has improved reliability by preventing leakage currents between neighboring memory cells and reading data from desired memory cells without errors may be provided.

According to embodiments of the present invention, a semiconductor memory cell having an asymmetric electrode structure in which a hole injection barrier at a p-type channel interface is increased by disposing a low work function metal in a source contact, thereby suppressing leakage current, and a high work function metal in a drain contact, thereby facilitating hole injection, thereby enabling stable read operation, may be provided.

Further, due to the capacitorless structure, a semiconductor memory cell may be provided in which the memory cell area is reduced, the process is simplified, high integration is facilitated, and inter-cell interference is reduced to improve readout margins.

Further, according to other embodiments of the present invention, a semiconductor memory device may be provided in which asymmetric electrode arrangement optimized for p-type semiconductor characteristics enables differentiated device design and improves read reliability even in large memory cell arrays.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a capacitorless semiconductor memory cell including two transistors, in accordance with one embodiment of the present disclosure.

FIG. 2 illustrates a semiconductor memory device including a semiconductor memory cell array including a plurality of semiconductor memory cells, according to one embodiment of the present invention.

FIG. 3 illustrates a semiconductor memory cell array including a diode to prevent leakage current, in accordance with one embodiment of the present invention.

FIG. 4 illustrates a source-drain contact region of a semiconductor memory cell with a semiconductor channel layer, in accordance with one embodiment of the present invention.

FIG. 5 illustrates a semiconductor memory device with a read transistor including an n-type semiconductor channel layer according to one embodiment of the present invention.

FIG. 6 illustrates current flow when a read transistor is configured with various contact materials in a semiconductor memory device according to one embodiment of the present disclosure.

FIG. 7 illustrates characteristics of a semiconductor memory device when a read transistor is configured with various contact materials in a semiconductor memory device according to FIG. 5 and one embodiment of the present invention.

FIG. 8 illustrates a semiconductor memory device 2000 with a read transistor including a p-type semiconductor channel layer that prevents leakage current according to one embodiment of the present invention.

FIG. 9 illustrates other read operations in a read transistor comprising a p-type semiconductor channel layer according to one embodiment of the present invention.

In the following description, the same or similar elements are labeled with the same or similar reference numbers.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to be limiting of the invention. As used herein, the singular forms "a", "an" and "the" are intended to include the plural forms as well, unless the context clearly indicates otherwise. It will be further understood that the terms “includes”, "comprises" and/or "comprising," when used in this specification, specify the presence of stated features, integers, steps, operations, elements, and/or components, but do not preclude the presence or addition of one or more other features, integers, steps, operations, elements, components, and/or groups thereof. In addition, a term such as a “unit”, a “module”, a “block” or like, when used in the specification, represents a unit that processes at least one function or operation, and the unit or the like may be implemented by hardware or software or a combination of hardware and software.

Reference herein to a layer formed "on" a substrate or other layer refers to a layer formed directly on top of the substrate or other layer or to an intermediate layer or intermediate layers formed on the substrate or other layer. It will also be understood by those skilled in the art that structures or shapes that are "adjacent" to other structures or shapes may have portions that overlap or are disposed below the adjacent features.

In this specification, the relative terms, such as "below", "above", "upper", "lower", "horizontal", and "vertical", may be used to describe the relationship of one component, layer, or region to another component, layer, or region, as shown in the accompanying drawings. It is to be understood that these terms are intended to encompass not only the directions indicated in the figures, but also the other directions of the elements.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Preferred embodiments will now be described more fully hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the disclosure to those skilled in the art.

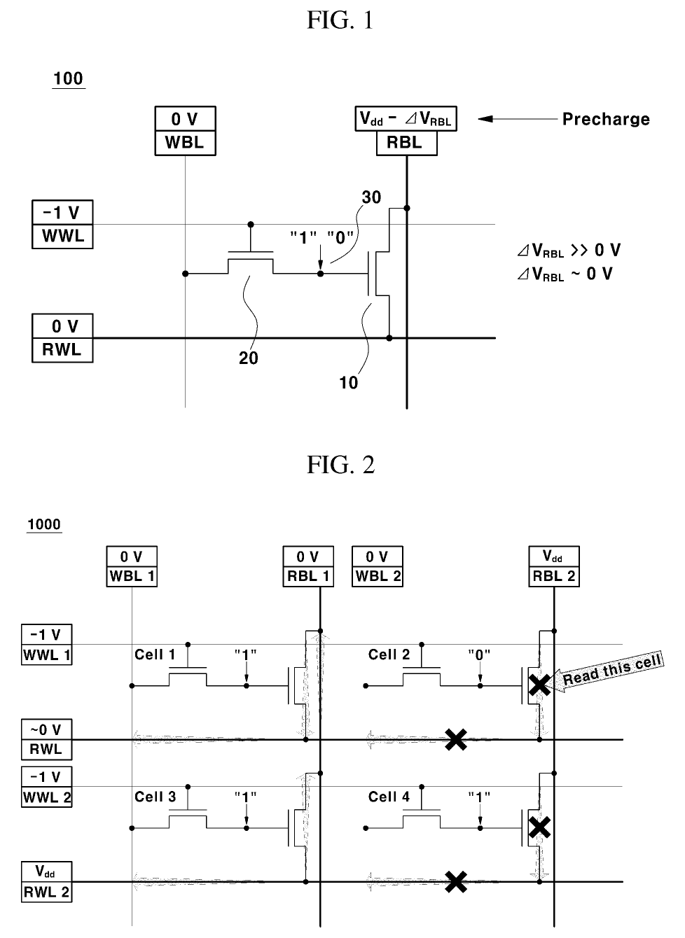

FIG. 1 illustrates a capacitorless semiconductor memory cell including two transistors in accordance with one embodiment of the present disclosure.

Referring to FIG. 1, a semiconductor memory cell (100) according to one embodiment of the present invention may include a first transistor 10 comprising a p-type oxide semiconductor channel layer formed on a substrate, and a second transistor 20 connected in series with the first transistor 10. It may also include a storage node 30, which is a path in which the first transistor 10 and the second transistor 20 are connected in series.

The semiconductor memory cell of the present invention may be a capacitor-less structure that includes two transistors and does not include a separate storage capacitor, and may include a write transistor for data write operations and a read transistor for read operations. For example, the first transistor 10 may be a read transistor, and the second transistor 20 may be a selective write transistor.

In one embodiment, the read transistor may have a source region connected to a read bit line (RBL) and a drain region connected to a read word line (RWL), and the write transistor may have a drain region connected to a write bit line (WBL) and a control electrode connected to a write word line (WWL).

Further, the semiconductor memory cell according to one embodiment of the present invention may store a charge in a storage node 30, which is a path in which the first transistor 10 and the second transistor 20 are connected in series.

The data read operation of these semiconductor memory cells is described as follows. In the data reading operation, the semiconductor memory cell first sets the bit line (SRBL) of the selected memory cell to the operating voltage (V_{dd}), i.e., precharges and floats the current so that the bit line of the selected semiconductor memory cell has the operating voltage value (V_{dd}). Next, the voltage of the read word line (RWL) of the selected semiconductor memory cell is set to 0V, and the data stored in the selected semiconductor memory cell is read from the voltage change of the bit line of the selected semiconductor memory cell (V_{RBL}). If the data of the selected semiconductor memory cell is 0, the bit line voltage change (V_{RBL}) remains close to 0. Conversely, if the data is 1, a voltage drop occurs within a certain time.

FIG. 2 illustrates a semiconductor memory device 1000 including a semiconductor memory cell array comprising a plurality of semiconductor memory cells 100, according to one embodiment of the present invention. Referring to FIG. 2, a read word line (RWL) associated with a semiconductor memory cell selected from the plurality of semiconductor memory cells for reading data may be set to 0 V, and another read word line (RWL) may be set to an operating voltage (V_{dd}). For example, when the selected semiconductor memory cell is cell 2, the read word line RWL 1 associated with cell 2 is set to 0 V, and the other read word line RWL 2 is set to the operating voltage (V_{dd}).

In this way, when a semiconductor memory cell containing only these two transistors and no capacitors is used, the read operation and the write operation may be separated. Therefore, when constructing a semiconductor memory cell array comprising a plurality of semiconductor memory cells, only the required data may be read and transferred to the buffer memory, which may provide an effect of increased efficiency.

However, in the above semiconductor memory device, there may be a problem that leakage current is generated depending on the state of the neighboring semiconductor memory cells sharing the word lines and bit lines of the selected semiconductor memory cell. For example, if the data of the selected semiconductor memory cell (cell 2) is 0, and the data of the three neighboring semiconductor memory cells (cells 1, 3, and 4) is 1, leakage current between the semiconductor memory cells may occur, which may interfere with the reading of the selected semiconductor memory cell.

To solve the problem of interference caused by such leakage current, the present invention presents an embodiment in which a diode for preventing leakage current is connected to the read bit line of the memory cell, or the source region of the read transistor and the diode region contact material are controlled.

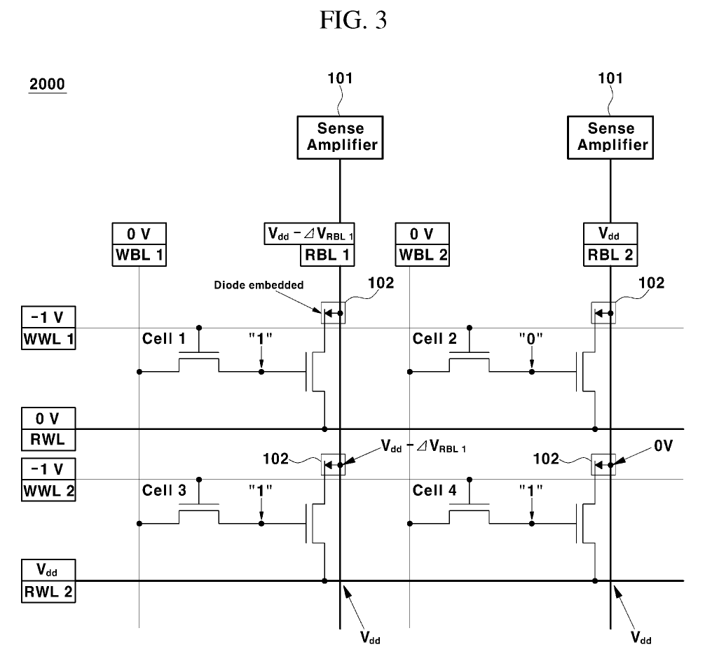

FIG. 3 is a drawing illustrating a semiconductor memory cell array 2000 including a diode for preventing leakage current, in accordance with one embodiment of the present invention.

Referring to FIG. 3, the semiconductor memory cell array 2000, according to one embodiment of the present invention, includes a plurality of semiconductor memory cells including write transistors and read transistors. As described in FIG. 1, each semiconductor memory cell of FIG. 3 includes a transistor for a data write operation and a transistor for a read operation. The transistor for data write operation has a drain region connected to a word bit line (WBL) and a control electrode connected to a write word line (WWL). The transistor for data read operation has a source region connected to the read bit line (RBL) and a drain region connected to the read word line (RWL).

The data read operation of such an array of semiconductor memory cells is described as follows. In the data reading operation, the semiconductor memory element first sets the bit line (SRBL) of the selected memory cell to the operating voltage (V_{dd}) i.e., precharges and floats the current so that the bit line of the selected memory cell has the operating voltage value (V_{dd}). Next, the voltage of the read word line (RWL) of the selected semiconductor memory cell is set to 0V, and the data stored in the selected semiconductor memory cell is read from the voltage change of the bit line of the selected semiconductor memory cell (V_{RBL}). If the data of the selected semiconductor memory cell is zero, the bit line voltage change (V_{RBL}) remains close to zero, and conversely, if the data is one, a voltage drop occurs within a certain time period.

A capacitorless semiconductor memory device according to one embodiment of the present invention includes a sensing amplifier 101 that applies an operating voltage value to a bit line, a semiconductor memory cell array comprising a plurality of semiconductor memory cells, and a diode 102 that is further connected to a source region of each read transistor and a read bit line.

That is, a read transistor included in the semiconductor memory cell array of the present invention includes a drain region, a control electrode, and a source region, and the diode 102 is positioned between the source region and the read bit line of the read transistor so that when an operating voltage value (V_{dd}) is applied to a word line of a non-selective semiconductor memory cell among the semiconductor memory cells included in the semiconductor memory cell array, leakage current from the read word line to the read bit line is blocked by the diode.

For example, in FIG. 3, when cell 1 is selected, cell 3 becomes a non-selective semiconductor memory cell but shares a read bit line with cell 1, so that the voltage of the read bit line connected to cell 3 becomes the operating voltage value (V_{dd}) minus the bit line voltage change (V_{RBL}) caused by cell 1. This may cause leakage current to flow from the drain region of the read transistor to the source region, but the diode has the effect of blocking the leakage current so that the memory cell read operation occurs more accurately.

Furthermore, in FIG. 3, when cell 1 is selected, since cell 4 is a non-selected memory cell, the read word line (RWL 2) is set to the operating voltage (V_{dd})and the other read word line (RWL 1) is set to 0 V, so that even if the voltage (V_{ds}) between the drain and source of cell 4 increases to the operating voltage value (V_{dd}), the diode blocks the leakage current so that the memory cell reading operation occurs more accurately. Furthermore, in this case, the voltage applied between the drain and source regions of the cell 4 is substantially equal to the operating voltage value (V_{dd}) minus the voltage applied to the diode (V_{diode}).

Therefore, according to one embodiment of the present invention, even if the read bit line voltage of the non-selective memory cell is set to 0 V and the voltage across the drain region and the source region of the non-selective memory cell is increased to V_{dd} -V_{diode,}the leakage current is blocked by the diode, thereby substantially increasing the operating voltage value (V_{dd}).

In addition, since the voltage value (V_{diode})applied to the diode is set to be less than the clamping voltage value (V_{cl}) provided by the separate clamping circuit, the voltage value that may be applied to the non-selected memory cell is increased compared to the case of using the clamping circuit, and the voltage fluctuation width of the bit line is sufficiently large, so that the data status of more memory cells may be accurately processed when adopted in a neuromorphic device for artificial intelligence.

In other words, in the case of a memory cell array applied to a neuromorphic device, the voltage drop rate of an arbitrary read bit line depends on the number of data 0s and 1s input to the read word connected to that read bit line, which is utilized as the principle of vector-matrix multiplication (VMM).

Therefore, the more zeros there are in the vector input to the read word line (RWL), the faster the read bit line voltage (V_{RBL}) will fall (assuming a 0V input). Also, when many memory cells (synapses) are connected to a single read bit line, the voltage across the read bit line must be large enough to accommodate the inputs from all memory cells. Therefore, according to the present invention, as described above, the voltage value (V_{diode}) applied to the diode is set to be less than the clamping voltage value (V_{cl}) provided by the separate clamping circuit, so that the voltage value that may be applied to the non-selected memory cell is increased compared to the case of using the clamping circuit, so that the voltage fluctuation range applied to the bit line is sufficiently large, which has the effect of accurately processing the data state of more memory cells when adopted in a neuromorphic device for artificial intelligence.

Furthermore, when the diode according to the present invention is adopted even when a clamping circuit is further included in parallel with the sensing amplifier according to an embodiment so that the minimum value of the voltage of the read bit line is the clamping voltage value, it has the effect of preventing leakage current between adjacent memory cells and eliminating interference between memory cells so that data may be read accurately.

In this case, even if a minimum value of the read bit line voltage is set using a clamping circuit, the read bit line voltage may have a voltage minimum value or higher, so a leakage current problem caused by data values of non-selected memory cells may still occur, and even if a minimum voltage value is set using a clamping circuit, adopting a diode according to an embodiment of the present invention has the effect of blocking a leakage current caused by data values of non-selected memory cells.

Next, another embodiment of the present invention will be described in which the diode operation capable of preventing leakage current that may occur between adjacent semiconductor memory cells as described above may be implemented directly in the read transistor.

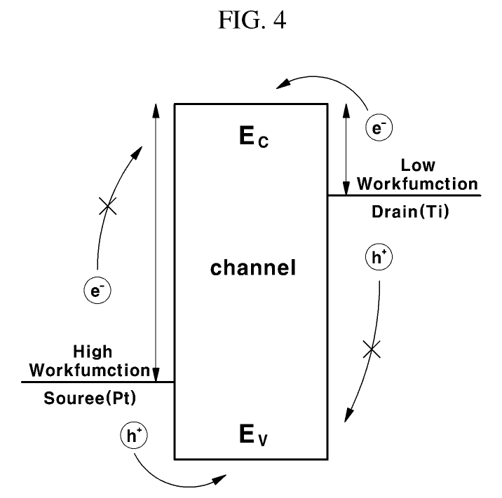

FIG. 4 illustrates a source-drain contact region forming a Schottky barrier according to a type of semiconductor channel layer in a semiconductor memory cell including a semiconductor channel layer according to one embodiment of the present invention.

Referring to FIG. 4, a transistor including an n-type semiconductor channel layer may have a charge carrier that is an electron (e-). In this case, in order for electrons to be injected from the source electrode into the n-type semiconductor channel layer, they must cross the conduction band Ec, which may act as a barrier to current flow if a Schottky barrier is formed.

Utilizing this feature, in a semiconductor memory cell comprising an n-type semiconductor channel layer according to one embodiment of the present invention, a metal with a high work function may be disposed at the source contact and a metal with a low work function may be disposed at the drain contact, thereby suppressing the injection of current from the source side and allowing only current flow from the drain side. Thus, a rectification effect that effectively blocks leakage current in the read operation of a semiconductor memory cell may be realized.

On the other hand, in a transistor comprising a p-type semiconductor channel layer, the charge carrier is a hole (h+), and the hole may move along the valance band (Ev). In this case, due to the nature of the energy band alignment, a metal with a higher work function may have a lower hole injection barrier as its Fermi level is closer to the balance band, and conversely, a metal with a lower work function may have a higher hole injection barrier, making hole injection difficult.

Therefore, a semiconductor memory cell comprising a p-type semiconductor channel layer according to one embodiment of the present invention may be designed to suppress current injection on the source side and allow only current flow on the drain side by placing a metal with a low work function on the source contact and a metal with a high work function on the drain contact. By doing so, a rectification effect may be realized that effectively blocks leakage current during the read operation of the semiconductor memory cell.

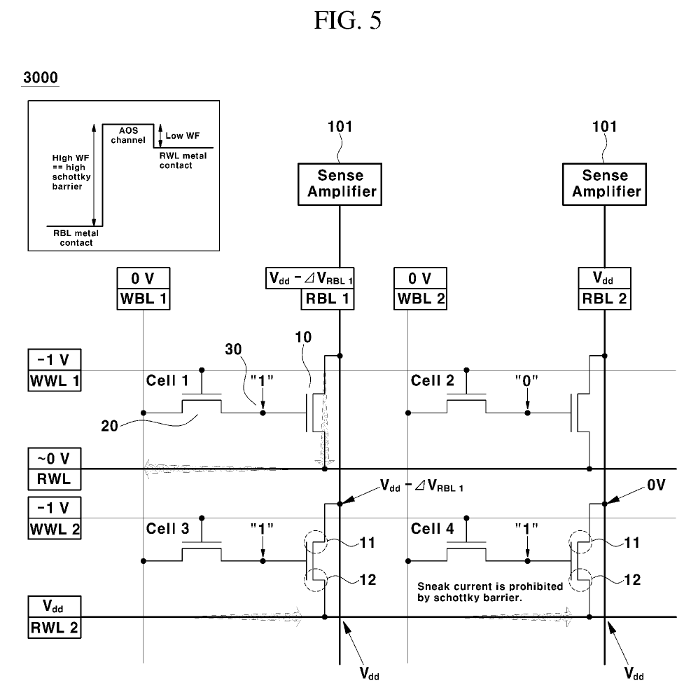

FIG. 5 is a diagram illustrating a semiconductor memory device 3000 including a read transistor comprising an n-type semiconductor channel layer that prevents leakage current according to one embodiment of the present disclosure.

Referring to FIG. 5, a capacitorless semiconductor memory device according to one embodiment of the present invention includes a plurality of memory cell arrays disposed in a cross-array structure on a substrate, a plurality of bit lines and a plurality of word lines connected to the memory cell arrays, a first transistor 10 and a second transistor 20 included in each of the memory cells, a source contact 11 contacting a source region of the first transistor and a drain contact 12 contacting a drain region of the second transistor, and a sensing amplifier connected to the bit lines.

The semiconductor memory device wherein the second transistor 20 and the first transistor 10 may be connected in series, and a charge may be stored in a storage node 30 in the path of the series connection. By utilizing the charge value stored in the storage node 30, the semiconductor memory device according to one embodiment of the present invention may realize a structure that does not include a capacitor.

In this case, the read transistor is implemented to effectively block the current flow from the drain region 12 to the source region 11. That is, the read transistor is formed using an IGZO semiconductor channel comprising at least one of indium, gallium, zinc, and oxygen, and the contact material of the source region 11 may be configured including a Schottky contact material, and the contact material of the drain region 12 may be configured as an Ohmic contact.

For example, the contact material of the source region may be formed of a material having a work function of 4.7 eV or greater, such that current flow from the drain region to the source region is effectively blocked. Ru, Au, Pd, Ni, Pt, or an alloy thereof may be used as the contact material of such a source region. Furthermore, the drain region of the read transistor may comprise at least one of Ti, TiN, Al, and alloys thereof to form an ohmic contact, and in some embodiments, a quasi ohmic contact.

For example, the read transistor may comprise an IGZO channel comprising at least one of indium, gallium, zinc, and oxygen, wherein the contact material of the source region is Pt or a Pt alloy material, and the drain region may comprise Ti or a Ti alloy material.

In one embodiment of the present invention, this configuration allows current to flow from the source region to the drain region while making it difficult for current to flow from the drain region to the source region, so that leakage current may have a blocking effect without installing additional diodes in the memory cell array, thereby reducing the processing difficulty and increasing the integration of the memory cell array while enabling accurate and error-free reading of data caused by the operation of the memory cell array.

For example, in FIG. 5, when Cell 1 is selected, Cell 3 becomes a non-selected memory cell but shares a read bit line with Cell 1, so the voltage on the read bit line connected to Cell 3 becomes the operating voltage value (V_{dd}) minus the bit line voltage change caused by Cell 1 (V_{RBL}), This may cause leakage current to flow from the drain region of the read transistor to the source region, but the above configuration of the drain region and source region has the effect of blocking the leakage current so that the memory cell read operation occurs more accurately.

In addition, when cell 1 is selected in FIG. 5, since cell 4 is a non-selected memory cell, the read word line (RWL 2) is set to the operating voltage (V_{dd}) and the other read word line (RWL 1) is set to 0V, so that even if the voltage (V_{dd}) between the drain and source of cell 4 increases to the operating voltage value (V_{dd}), the above configuration of the drain area and the source area has the effect of blocking the leakage current so that the memory cell reading operation occurs more accurately.

The capacitorless semiconductor memory device of FIG. 5 may further include a clamping circuit connected in parallel with the sensing amplifier, and the clamping circuit may cause a minimum value of the voltage of the read bit line to be a clamping voltage value.

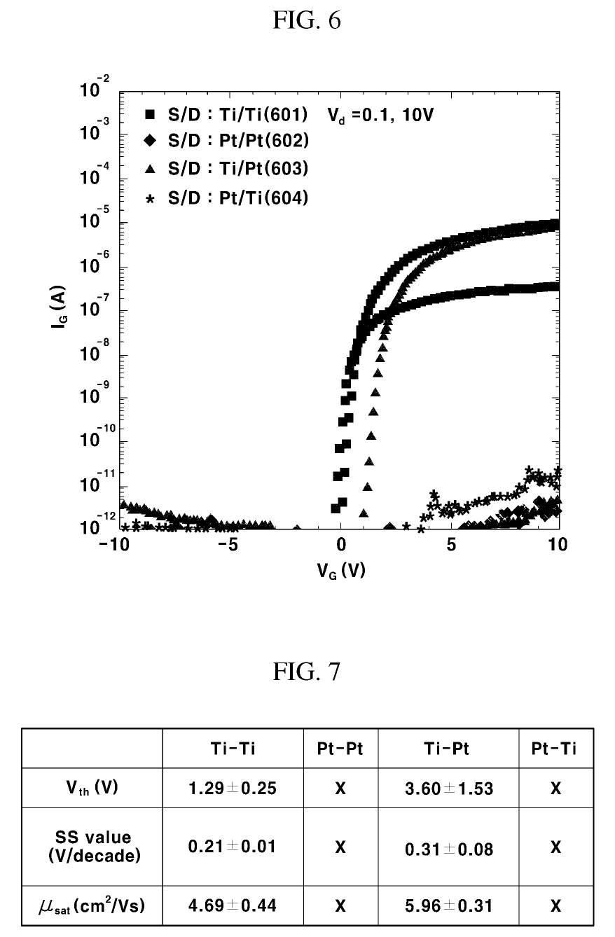

FIG. 6 is a diagram illustrating current flow when a read transistor is configured with various contact materials in a semiconductor memory device 3000 according to FIG. 5 and one embodiment of the present invention.

Referring to FIG. 6, when both the source region and the drain region are composed of Ti or Ti alloy material, current flows regardless of the direction of the current formed from the drain region to the source region (601).

When both the source region and the drain region are composed of Pt or Pt alloy material, current flows poorly regardless of the direction of the current formed (602).

If the source region is composed of Ti or Ti alloy material and the drain region is composed of Pt or Pt alloy material, current flows regardless of the current direction (603).

On the other hand, if the source region is composed of a Pt or Pt alloy material as described above and the drain region is composed of a Ti or Ti alloy material, current flows from the drain region to the source region, but not from the source region to the drain region, depending on the direction of the current that is formed (604).

Therefore, when the source region is configured with a Pt or Pt alloy material as described above, and the drain region is configured with a Ti or Ti alloy material, current flow from the source region to the drain region may be maintained while current flow from the drain region to the source region is made difficult, so that leakage current may have a blocking effect without installing additional diodes in the memory cell array, which has the effect of reducing the process difficulty of the memory cell array and increasing its integration, while accurately reading data caused by the operation of the memory cell array without error.

FIG. 7 is a diagram illustrating characteristics of a semiconductor memory device when a read transistor is configured with various contact materials in a semiconductor memory device 3000 according to FIG. 5 and one embodiment of the present invention.

Referring to FIG. 7, when both the source region and the drain region are composed of Ti or Ti alloy material, the read transistor threshold voltage value (Vₜₕ) is 1.29+0.25 V to 1.29-0.25 V, the subthreshold swing (SS) value is 0.21+0.01 V to 0.21-0.01 V/decade, µ_{sat (}carrier mobility) ranges from 4.69+0.44 V to 4.69-0.44 V cm²/Vs. Therefore, if both the source and drain regions are composed of Ti or Ti alloy materials, bidirectional current flows and leakage current occurs.

If both the source and drain regions are composed of Pt or Pt alloy materials, current flows poorly regardless of the direction of the current formed.

Next, if the source region is composed of Ti or Ti alloy material, and the drain region is composed of Pt or Pt alloy material, the read transistor threshold voltage value (Vₜₕ) is in the range of 3.60+1.53V to 3.60-1.53V, the subthreshold swing (SS) value is in the range of 0.31+0.08V to 0.31-0.08 V/decade, and µₛₐₜ(carrier mobility) ranges from 5.96+0.31 V to 5.96-0.31 V cm²/Vs. Thus, when both the source region and the drain region are composed of Ti or Ti alloy materials, bidirectional current flows, and leakage current is generated.

On the other hand, if the source region is composed of Pt or a Pt alloy material as described above and the drain region is composed of Ti or a Ti alloy material, current flows from the source region to the drain region, but not from the drain region to the source region, depending on the direction of the current formed (604).

Therefore, when the source region is configured with a Pt or Pt alloy material as described above and the drain region is configured with a Ti or Ti alloy material, the leakage current may be blocked without installing an additional diode in the memory cell array by maintaining the current flow from the source region to the drain region while making it difficult for the current to flow from the drain region to the source region, thereby having the effect of reducing the process difficulty of the memory cell array and increasing its integration, while accurately reading the data caused by the operation of the memory cell array without error.

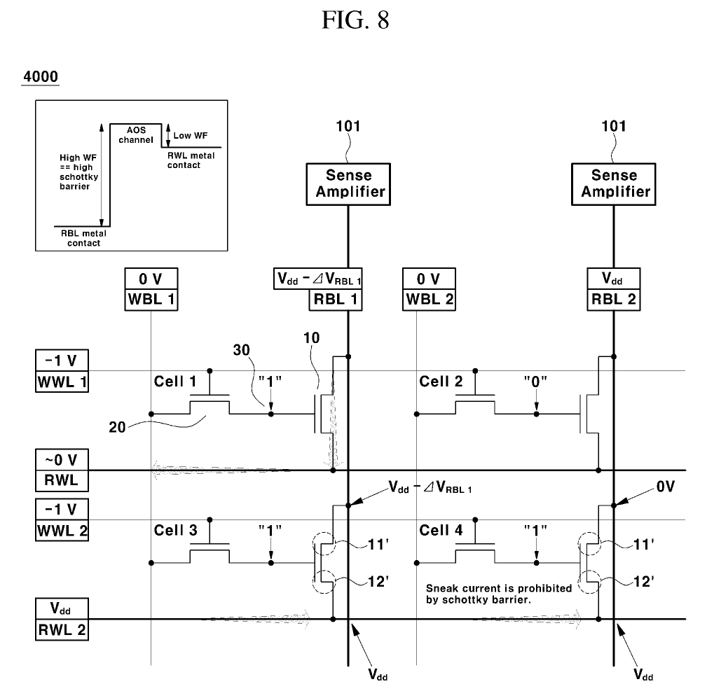

FIG. 8 illustrates a semiconductor memory device 4000 including a read transistor comprising a p-type semiconductor channel layer that prevents leakage current according to one embodiment of the present invention.

Referring to FIG. 8, a capacitorless semiconductor memory device according to one embodiment of the present invention includes a plurality of memory cell arrays disposed in a cross-array structure on a substrate, a plurality of bit lines and a plurality of word lines connected to the memory cell arrays, a first transistor 10' included in each of the memory cells, and a second transistor 20', a source contact 11' contacting a source region of the first transistor and a drain contact 12' contacting a drain region of the second transistor, and may include a read circuit 101 connected to the bit lines and performing a read operation.

The semiconductor memory device may be connected in series between the second transistor 20' and the first transistor 10', and a charge may be stored in a storage node 30' in the path of the series connection. By utilizing the charge value stored in the storage node 30', the semiconductor memory device according to one embodiment of the present invention may realize a structure that does not include capacitors.

The memory cells included in the plurality of memory cell arrays may all be capacitorless structures that do not include a separate storage capacitor, and the memory cell (Cell N) may include a memory element having a p-type semiconductor channel layer on the first transistor (10').

The plurality of bit lines and plurality of word lines may include a read bit line (RBL) and a write bit line (WBL) pair and a read word line (RWL) and a write word line (WWL) pair, respectively, which may be connected to the memory cell array and optionally operable. Further, the read circuitry may be connected to the read bit line and write bit line pair to perform a read operation.

In this case, the read transistor may be implemented to effectively block the current flow from the drain region 12' to the source region 11'. The read transistor may be formed using an IGZO semiconductor channel comprising at least one of indium, gallium, zinc, and oxygen, wherein the contact material of the drain region 12' may comprise an Ohmic contact material, and the contact material of the source region 11' may comprise a Schottky contact material. For example, the contact material of the source region 11' may be formed of a material with a work function of less than 4.7 eV such that current flow from the drain region 12' to the source region 11' is effectively blocked. Such contact materials of the source region 11' may include at least one of Ag, Ti, TiN, Al, and alloys thereof. They may increase the metal Fermi level, thereby increasing the hole injection barrier and thus blocking current flow. The contact material of the drain region 12' of the read transistor is a high work function material with a work function of at least 4.7 eV, such that Ru, Au, Pd, Ni, Pt, or alloys thereof may be used, and may constitute an ohmic contact, or in some embodiments, a quasi ohmic contact.

In one embodiment of the present invention, such a configuration may allow current flow from the source region to the drain region, while impeding current flow from the drain region to the source region, such that leakage current is blocked without requiring additional diodes to be installed in the semiconductor memory cell array. In addition, it has the effect of reducing the process difficulty of the semiconductor memory cell array and increasing the integration density, while accurately reading data caused by the operation of the semiconductor memory cell array without errors.

For example, in FIG. 8, when Cell 1 is selected, Cell 3 becomes a non-selected memory cell but shares a read bit line with Cell 1, so the voltage of the read bit line connected to Cell 3 becomes the operating voltage value (V_{dd}) minus the bit line voltage change (V_{RBL})caused by Cell 1, This may cause leakage current to flow from the drain region 12' of the read transistor to the source region 11', but the above configuration of the drain region 12' and the source region 11' has the effect of blocking the leakage current so that the read operation of the semiconductor memory device occurs more accurately.

Furthermore, in FIG. 8, when cell 1 is selected, the read word line (RWL 2) is set to the operating voltage (V_{dd}), and the other read word line (RWL 1) is set to 0 V to drain cell 4, since cell 4 is a non-select semiconductor memory cell, Even if the voltage (V_{ds})between the sources increases to the operating voltage value (V_{dd}), the above configuration of the drain region 12' and the source region 11' has the effect of blocking the leakage current and enabling the reading operation of the semiconductor memory device to occur more accurately.

This effect is based on the difference in the Schottky barrier formation mechanism for the hole injection barrier. Therefore, even if the same asymmetric electrode structure is applied, differences may occur between the n-type semiconductor channel layer and the p-type semiconductor channel layer in the current injection and blocking mechanism, the electrode arrangement, and the way the rectification characteristics of the device are realized. Furthermore, when a p-type semiconductor channel layer according to one embodiment of the present invention is applied to a read transistor, in addition to the change of the charge carrier from an n-type semiconductor channel layer to a hole, there are additional advantages, such as the following in terms of circuit operation.

FIG. 9 illustrates different readout behaviors in a read transistor comprising a p-type semiconductor channel layer according to one embodiment of the present invention.

Referring to FIG. 9, it may be seen that a semiconductor memory cell comprising an nMOS write transistor and an nMOS read transistor operates in such a way that the read word line (RWL) starts in a high state during a read operation, switches to a low voltage at the time of sensing, and determines the data through whether the read bit line (RBL) drops in voltage. In this case, in a situation where the voltage of the storage node SN decreases due to the capacitive coupling of the capacitor due to the voltage drop of the write word line (WWL) during the write operation, the voltage drop of the read word line (RWL) also causes the coupling, so the voltage of the storage node SN may be further decreased. Thus, the voltage difference between read '0' and read '1' may become insufficient, thereby reducing the sensing margin and reducing the reliability of data discrimination.

However, in a semiconductor memory cell comprising an nMOS write transistor and a pMOS read transistor including a p-type semiconductor channel layer according to one embodiment of the present invention, the read word line (RWL) starts in a low state at the time of reading operation and switches to a high voltage at the time of sensing, and data may be discriminated according to whether the voltage of the read bit line (RBL) rises. In this case, even if the voltage charge of the storage node (SN) is generated due to the voltage drop of the write word line (WWL), the coupling caused by the rise of the read word line (RWL) voltage may provide a compensation effect that partially offsets the voltage drop of the storage node (SN). Thus, the voltage difference between read '0' and read '1' may be more clearly secured, thereby improving the sensing margin, and the operation reliability and read accuracy of the memory may be improved.

The semiconductor memory device and the operation method of the semiconductor memory device according to one embodiment of the present invention may read selected cells without interference from neighboring cells, and may therefore be used not only in memory but also in neuromorphic devices for artificial intelligence, and may also be used in the field of Vector Matrix Multiplication (VMM) technology. In other words, according to the embodiment of the invention described above, the effect of the invention is maximized when applied to neuromorphic devices for artificial intelligence by blocking leakage currents that may flow to neighboring cells, excluding data interference between neighboring cells, and accurately reading only data in selected memory cells.

While the present disclosure has been described with reference to the embodiments illustrated in the figures, the embodiments are merely examples, and it will be understood by those skilled in the art that various changes in form and other embodiments equivalent thereto can be performed. Therefore, the technical scope of the disclosure is defined by the technical idea of the appended claims.

The drawings and the forgoing description gave examples of the present invention. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A semiconductor memory device, comprising:
a plurality of a semiconductor memory cell arrays comprising a plurality of semiconductor memory cells including a write transistor and a read transistor, the read transistor including a drain region, a control electrode, and a source region;
a diode connected to the source region of the read transistor; and
a sensing amplifier in connection with a read bit line,
wherein the semiconductor memory device has a capacitorless structure that does not include a storage capacitor.

2. The device of claim 1, wherein leakage current from a read word line to the read bit line is blocked by the diode when an operating voltage value (V_{dd}) is applied to a non-selective semiconductor memory cell among the semiconductor memory cells included in the semiconductor memory cell arrays.

3. The device of claim 1, further comprising:
a clamping circuit in parallel connection with the sensing amplifier,
wherein the clamping circuit causes a minimum value of a voltage on the read bit line to be a clamping voltage value.

4. The device of claim 1, when the read bit line voltage of a non-selected semiconductor memory cell of the semiconductor memory cell is set to 0V and the read word line voltage is set to an operating voltage value (V_{dd}), wherein a voltage value between a drain region and a source region of the non-selected semiconductor memory cell is a value of the operating voltage value (V_{dd}) minus a diode voltage value (V_{diode}).

5. The device of claim 4, wherein the diode voltage value (V_{diode})is set below a clamping voltage value (V_{cl}) provided by the clamping circuit.

6. A semiconductor memory device, comprising:
a plurality of semiconductor memory cell arrays including a first transistor and a second transistor, disposed in a cross-array structure on a substrate;
a plurality of read bit line (RBL) and write bit line (WBL) pairs and a plurality of read word line (RWL) and write word line (WWL) pairs associated with the semiconductor memory cell arrays; and
a read circuitry connected to the pairs of read bit lines and write bit lines to perform a read operation,
wherein the first transistor includes an n-type semiconductor channel layer, a source contact in contact with a source region, and a drain contact in contact with a drain region, and is connected in series with the second transistor, and the first transistor is a read transistor, and the second transistor is a write transistor, and the source contact comprises a high work function metal to form a Schottky barrier at an interface with the n-type semiconductor channel layer, thereby blocking leakage current from the read word line to the read bit line in an unselected memory cell, and the drain contact comprises a low work function metal to facilitate the movement of electrons, and the semiconductor memory device has a capacitorless structure that does not include a storage capacitor.

7. The device of claim 6, wherein the first transistor comprises an IGZO channel comprising at least one of indium, gallium, zinc, and oxygen.

8. The device of claim 6, wherein source contact of the first transistor comprises a material having a work function of at least 4.7 eV.

9. The device of claim 6, wherein the source contact of the first transistor comprises Ru, Au, Pt Ni, Pt, or an alloy thereof.

10. The device of claim 6, wherein the drain contact of the first transistor comprises a material constituting ohmic contact.

11. The device of claim 6, wherein the drain contact of the first transistor comprises at least one of Ti, TiN, Al, and alloys thereof.

12. The device of claim 6, wherein the read transistor comprises an IGZO channel comprising at least one of indium, gallium, zinc, and oxygen, wherein the source contact comprises Pt or a Pt alloy material, and the drain contact comprises Ti or a Ti alloy material.

13. The device of claim 6, further comprising:
a clamping circuit in parallel connection with the sensing amplifier,
wherein the clamping circuitry causes a minimum value of a voltage on the read bit line to be a clamping voltage value.

14. A semiconductor memory device, comprising:
a plurality of semiconductor memory cell arrays including a first transistor and a second transistor, disposed in a cross-array structure on a substrate;
a plurality of read bit line (RBL) and write bit line (WBL) pairs and a plurality of read word line (RWL) and write word line (WWL) pairs associated with the semiconductor memory cell arrays; and
a read circuitry connected to the pairs of read bit lines and write bit lines to perform a read operation,
wherein the first transistor includes a p-type semiconductor channel layer, a source contact contacting a source region, and a drain contact contacting a drain region, and is connected in series with the second transistor, and the source contact comprises a low work function metal to increase a hole injection barrier at the interface with the p-type semiconductor channel layer to block leakage current from the read word line to the read bit line in an unselected memory cell, and the drain contact comprises a high work function metal to facilitate hole injection, and the semiconductor memory device has a capacitorless structure that does not include a storage capacitor.

15. The device of claim 14, wherein the low work function metal comprises aluminum, titanium, silver, or a combination thereof.

16. The device of claim 14, wherein the high work function metal comprises platinum, ruthenium, palladium, or combinations thereof.

17. The device of claim 14, wherein the first transistor comprises a p-type oxide semiconductor channel layer.

18. The device of claim 14, wherein a storage node in a path in which the first transistor and the second transistor are connected in series stores a charge.

19. The device of claim 14, wherein the first transistor is a read transistor, and the second transistor is a write transistor.

20. The device of claim 14, wherein a read margin of the entire semiconductor memory cell arrays is formed by suppression of the leakage current.
